(19) United States
(12) Patent Application Publication
(10) Pub. No.: US 2025/0374474 A1
(43) Pub. Date: Dec. 4, 2025

(54) Automation Assembly with a Housing

(71) Applicant: Siemens Aktiengesellschaft, Muenchen (DE)

(72) Inventors: Gunter GRIESSBACH, Gelenau (DE); Lydia Rowena NEUBERT, Chemnitz (DE)

(21) Appl. No.: 19/226,299

(22) Filed: Jun. 3, 2025

(30) Foreign Application Priority Data
Jun. 4, 2024 (EP) 24179761

(51) Int. Cl. H05K 7/20; H05K 5/02

(52) U.S. Cl. CPC H05K 7/20127; H05K 5/0214; H05K 7/20427

(57) ABSTRACT

An automation assembly with a housing includes a printed-circuit board in parallel between the left side and a right side of the housing, and lower and uppers sides that are at least partly formed as ventilation grilles to provide convection cooling within the housing, wherein a housing wall of the left and right sides each have a screening layer (AS) that has a first material layer and a second material layer, the first material layer is formed as a barrier layer that reflects thermal radiation, the second material layer is formed as a permeable layer that absorbs thermal radiation and only partly reflects it, and where the screening layer is arranged in the housing walls such that the barrier layer is arranged in the direction of an outer side of the housing and the permeable layer is arranged in the direction of an inner side of the housing.

### BACKGROUND OF THE INVENTION

### 1. Field of the Invention

The invention relates to an automation assembly with a housing, which has a rear side, a front side, a lower side, an upper side, a left side and a right side, where a printed-circuit board is arranged in the housing in parallel between the left side and the right side of the housing, and where the lower side and the upper side are formed at least in part as a ventilation grille in order to make it possible to cool the inside of the housing by convection.

### 2. Description of the Related Art

EP 4 169 361 A1 discloses a base module with at least one function module. The base module contains a basic housing with a circulation channel through which a flow of air can be guided. This channel is provided with circulation openings, which make a connection to the inside of the function housing possible. When the coupling openings of the function module are connected to the circulation openings of the base module, a closed circuit arises. The flow of air can circulate in this circuit, which ensures an efficient and even cooling of the base module.

What all electronic assemblies mentioned in the prior art have in common is that heat is generated by the components, which becomes evident from the development of heat. This heat development must be counteracted so that the modules are not overloaded and, as a consequence of this, their reliability suffers or the result is that they fail. A maximum ambient temperature is defined for the assemblies. If the assemblies are operated at the maximum ambient temperature, the internal temperatures of the components rise above the ambient temperature because of their heat losses. It must be ensured that the components are not thermally overloaded in such cases. The criterion in this case is adherence to the maximum chip temperature specified in the data sheet.

Through corresponding measures, precautions are taken for the heat to be able to be dissipated into the environment. Three physical principles operate in such cases, thermal conduction, convection and thermal radiation. If the assembly in question is operated in the vicinity of other assemblies that likewise emit heat, then the result is an additional input of heat from the assemblies in question.

In such cases, there is always an equalization from the hotter side to the cooler side. Since automation technology products are primarily constructed in a modular manner, many assemblies are arranged immediately alongside one another and form an automation device in this way.

For the case of a modular-design automation device in which an assembly with a high power dissipation is operated in each case to the left and to the right of an assembly, it can occur that overheating of the assembly in the middle results. If the desire is to take account of this possible overheating, the result can be higher costs for components with greater temperature resistance. Higher costs are a clear competitive disadvantage.

### SUMMARY OF THE INVENTION

In view of the foregoing, it is an object of the present invention is to provide an automation assembly that, despite heat-emitting neighboring assemblies, can be operated in a temperature-proof way without using components with a higher thermal stability.

This and other objects and advantages are achieved in accordance with the invention in an assembly stated at the outset by a housing wall of the left side and a housing wall of the right side each having a screening layer, where the screening layer has a first material layer and a second material layer, the first material layer is formed in this case as a barrier layer that reflects a thermal radiation, the second material layer is formed in this case a permeable layer that absorbs a heat radiation and only reflects it in part, wherein the screening layer is arranged in the housing walls in such a way that the barrier layer is arranged in the direction of an outer side of the housing and the permeable layer is arranged in the direction of the inner side of the housing.

The disclosed modular apparatus offers a solution for the problem of dissipating heat in electrical assemblies. By contrast with earlier more complex constructions, the inventive modular apparatus makes efficient cooling possible by a simple structure. The apparatus consists of a carrier rail and a number of assemblies that are mounted on the rail. A space is produced between the rear wall of the assemblies and the carrier rail, which serves as a channel for a cooling medium. One of the assemblies generates a vacuum, which conveys the cooling medium through the space and into the inside of the other assemblies, in order to cool the assemblies. This system is especially effective because, by concatenating the assemblies, it forms an end-to-end flow channel that extends over the entire length of the apparatus. Sealing elements at the ends of the channel prevent the cooling air from escaping, whereby an optimal cooling is guaranteed. The invention is characterized by low constructive outlay and high efficiency and is therefore a low-cost solution for heat management in modular electrical systems.

The invention presents a thermal diode, having for example a film with a reflecting metal on one side and a heat-absorbing lacquer on the other side. The automation assembly is only intended to handle its own power dissipation, which leads to a lower-cost and more flexible product configuration. By comparison with known technology, this improves the heat management efficiency, without which the modes of operation would have to be restricted or more heat-resistant components are needed.

The invention thus provides a screening layer for the housing, which reflects the heat radiation from the outside and absorbs the heat radiation from the inside, while existing technologies are based on the reduction of power dissipation or the use of more thermally stable components. Heat transmission paths and costs are reduced by the invention without the need to restrict modes of operation or for more thermally stable components.

In a further embodiment, the screening layer is formed as a layered film, which has a core material that is coated on both sides, one side has a reflecting metal layer vapor-deposited on it, and the other side is provided with a lacquer that has a heat-absorbing effect.

As an example a layered film could be applied to the housing walls to the neighboring sides or this coating is integrated into the housing. The coating of a space blanket is produced in this way, for example. With this material, the degree of reflection of the silver side, at 0.99, is almost ideal. The golden side (lacquered) only has a degree of reflection of 0.5. A reflection factor multiplied by an absorption factor directly produces a result of 1, consequently the thermal radiation for the direction of the silver side is almost completely blocked, but in the opposite direction 50% is let through.

For a modular structure consisting of a number of automation assemblies, which are arranged next to one another and have a backplane bus for communication with one another, where the rear side is configured for detachable mounting on an assembly carrier, a further improvement is achieved by the housing wall of the left side and the housing wall of the right side, each having a spacer oriented outwards. What is achieved by this is that the housing walls of neighboring assemblies cannot touch one another over their full surface.

In a specific embodiment, the spacer is formed as a bar. Thus a bar is additionally attached to the outer housing wall to prevent direct contact with neighboring assemblies and to reduce thermal conduction. Through these measures, each assembly only has to tolerate its own power dissipation and is better protected against entry of heat from neighboring assemblies, which reduces the need for expensive temperature-proof components. Moreover, the conception of new products is facilitated by improved heat management and competitiveness is improved.

Apart from the bar itself, there is now necessarily always air between the housing walls. Thus the thermal conductivity of an assembly is significantly reduced. The thermal conductivity of air, at 0.025, is significantly lower compared to that of plastic at between 0.25 and 0.5.

A modular apparatus comprising at least one first, one second and one third automation assembly can thus even be operated at higher ambient temperatures.

This solution makes possible a more cost-efficient configuration of the system, improves the integration of new modules into existing systems and contributes to a stable overall performance. The specific improvements that are brought about by the disclosed embodiments of the invention comprise an increased tolerance of the assemblies to external heat sources and cost reduction for the system as a whole resulting therefrom, because no additional measures for managing the input of heat from outside are required.

In summary, the disclosed embodiments of the invention solve the problem of the effective removal of heat from electronic assemblies by a thermal diode, which makes thermal transmission in one direction possible. By employing reflecting and absorbing layers in combination with a constructional method for minimizing the conduction of heat, assemblies are protected from overheating and additional costs for more thermally-stable components are avoided.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The drawing shows an exemplary embodiment of the invention, in which:

FIG. 1 shows an automation assembly in a three-dimensional view in accordance with the invention;

FIG. 2 shows a modular structure in accordance with the prior art;

FIG. 3 shows the principle of reflection and absorption at a screening layer;

FIG. 4 shows a modular structure with the automation assemblies in accordance with the invention;

FIG. 5 shows the modular structure with the automation assemblies in accordance with the invention, where the central automation assembly is shown with a cut-away section; and

FIG. 6 shows a detail from FIG. 5.

### DETAILED DESCRIPTION OF THE EXEMPLARY EMBODIMENTS

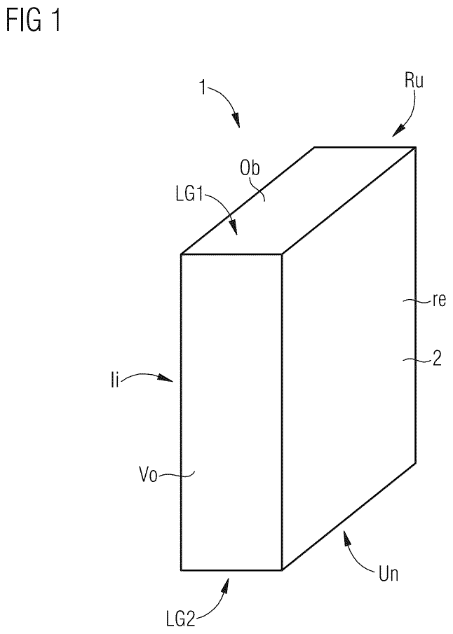

Shown in FIG. 1 is an automation assembly 1 with a housing 2. The housing 2 has a rear side Ru, a front side Vo, a lower side Un, an upper side Ob, a left side Ii and a right side re. Arranged in the housing 2 is a first printed-circuit board LG1 in parallel between the left side Ii and the right side re of the housing 2. The lower side Un and the upper side Ob are at least partly embodied as a first ventilation grille LG1 and a second ventilation grille LG2 in order to make convection cooling in the inside of the housing 2 possible.

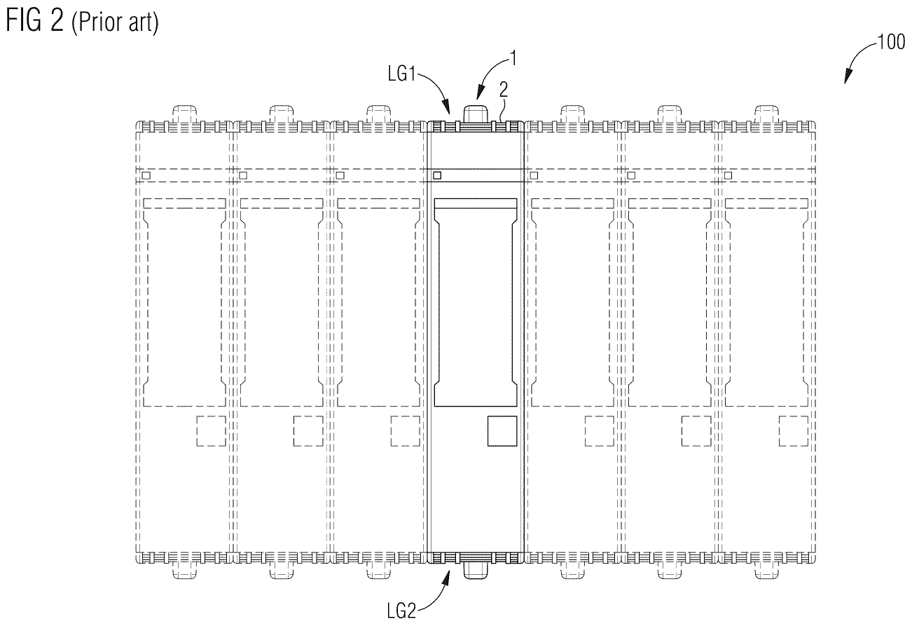

FIG. 2 shows a conventional modular apparatus 100 comprising a number of automation assemblies. During the operation of electronic automation assemblies, a dissipation of heat is generated by components on a printed-circuit board LP, which makes itself evident by the development of heat. This development of heat must be counteracted, so that the components are not overloaded and as a consequence of this the reliability suffers or this results in the failure of the automation assembly. An individual automation assembly 1 can already be cooled down by a flow of air through the ventilation grille LG1, LG2 arranged above and below it. Despite this, a maximum ambient temperature is defined for the automation assemblies. If the automation assemblies are operated at a maximum ambient temperature, then the internal temperatures of the components on the printed-circuit board LP also rise, due to their heat dissipation. Above this ambient temperature, it must be ensured that the components are not thermally overloaded. In such cases, the criterion in this case is adherence to a maximum chip temperature (junction temperature) given in the data sheet. Through corresponding measures, precautions are taken to enable the heat to be emitted into the environment, in particular through the ventilation grille LG1, LG2. Three physical principles act in the development of heat, thermal conduction, convection and thermal radiation.

If, as shown in FIG. 2, the automation assembly 1 is operated in the vicinity of other assemblies, here in particular in the middle of three other automation assemblies arranged on its left-hand side and likewise three automation assemblies 1 arranged on its right-hand side, this results in an additional input of heat from the neighboring automation assemblies into the automation assembly 1 arranged in the middle. In such cases, there is always an equalization of the thermal radiation or thermal transmission from a warmer side to a cooler side. The automation assemblies 1 have a modular structure as a rule, i.e. many assemblies are arranged directly next to one another, As result, an automation device or a modular apparatus 100 is formed in this way.

A very inconvenient case could occur if, as shown in FIG. 2, three assemblies with the highest heat dissipation occurring in a product family are each operated to the left and to the right of an automation assembly 1 in question. In this type of operation, the result can easily be an overloading of the automation assembly arranged in the middle.

Previously, attempts have been made to reduce the heat dissipation of an automation assembly 1 by not all channels of a module being able to be operated at the same time, for example, a so-called derating has been introduced. This, however, is a serious restriction for the users of the automation assemblies. As an alternative, more temperature-resistant components can be employed, but this increases the costs.

The idea of the underlying invention is to better isolate the automation assembly 1 in question from the influences of neighboring assemblies.

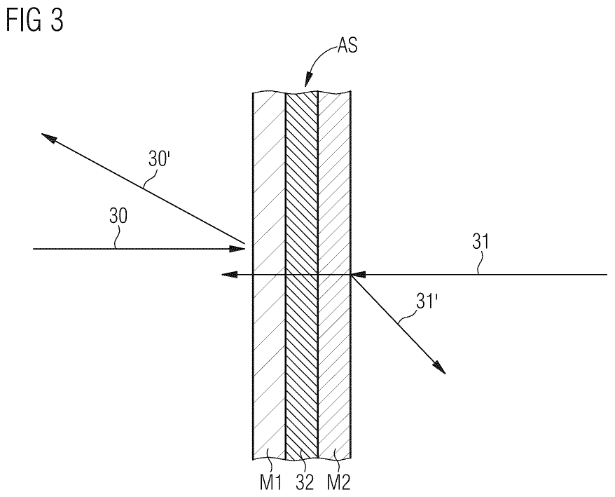

FIG. 3 illustrates the inventive principle. A screening layer is arranged in each case in a housing wall of the left side Ii and in a housing wall of the right side re. The screening layer AS has a first material layer M1 and a second material layer M2, the first material layer M1 is formed here as a barrier layer, which reflects radiated heat, the second material layer M2 is formed as a permeable layer, which absorbs further radiated heat 31 and only partly reflects it. Thus, the screening layer AS is arranged in housing walls such that the barrier layer is arranged in the direction of an outer side of the housing 2 and the permeable layer is arranged in the direction of the inner side of the housing 2. If radiated heat 30 now acts on the automation assembly 1, then, due to the first material layer M1, this is almost 99% thrown back as a reflection 30′ of the external radiated heat. Inside the automation assembly 1, on the other hand, internal radiated heat 31 is almost 50% absorbed due to the second material layer M2 and 50% is reflected as a reflection 31′ of the inner radiated heat.

The screening layer AS is formed as a layered film, which has a core material 32, where this core material 32 is coated on both sides. Accordingly, one side has a vapor-deposited metal coating applied to it, and the other side is provided with a lacquer, which has a heat-absorbing effect. The behavior corresponds to that of a diode in electronics. A film/barrier layer as screening layer AS can be considered as a thermal diode. A suitable coating on the permeable side enables significantly higher degrees of absorption to be achieved. The characteristics of the thermal diode are thus significantly improved.

The principle shown with FIG. 3 significantly effects a thermal radiation input into an automation assembly 1. Since, if the heavily reflecting side is directed outwards, the heat inputs from neighboring assemblies can be drastically restricted.

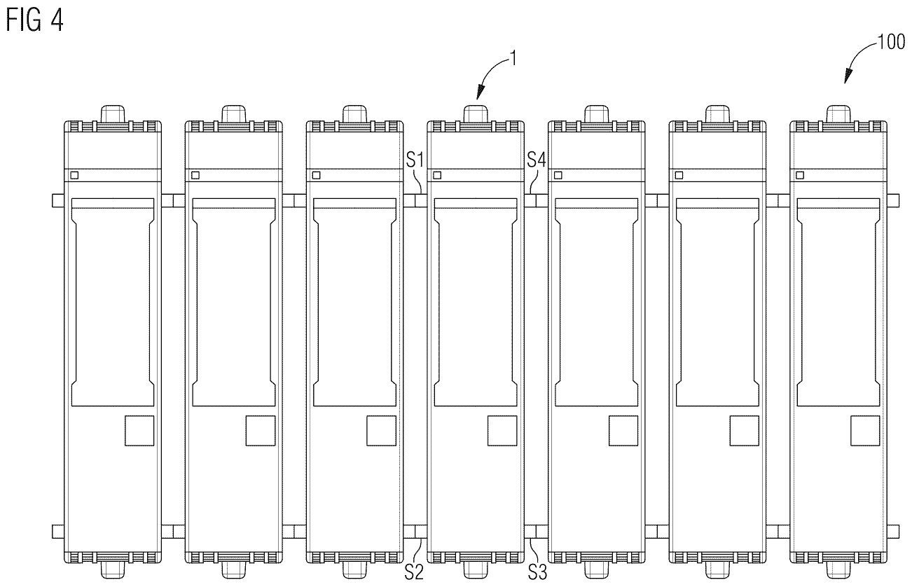

FIG. 4 shows a combination of the embodiment with the screening layer AS and an additionally introduced spacer means. The automation assembly 1 is configured for a modular structure consisting of a number of automation assemblies 1, which are arranged next to one another, and these can communicate with one another via a backplane bus for communication. As a result, the rear side is formed, as a rule, for a detachable mounting on an assembly carrier. In addition to the screening layer, the housing wall of the left side Ii and the housing wall of the right side re each have a spacer oriented outwards. The spacer is formed as a first bar S1, a second bar S2, a third bar S3 and a fourth bar S4.

What is achieved by this combination of the two methods, namely screening layer AS and spacer, is that the automation assemblies only have to deal with their own power dissipation and are not additionally heated by neighbors that especially develop heat.

Thermal conductance and thermal radiation have a significant share in the heat emitted by electronic assemblies. Together with convection, around a third is produced in each case for each type of transmission. If the automation assemblies 1 are formed as proposed, then the problem of outside input of radiated heat 30 from neighboring assemblies is significantly ameliorated. These countermeasures give rise to the following advantages:
unnecessary additional costs for temperature-resistant components are avoided,
a modular system can be formed so that the mutual influences are reduced and in total can be employed more flexibly in heat-affected environments,
new automation assemblies can be integrated more easily into existing systems, where the behavior of the system is more stable and less dependent on the arrangement of the automation assembly in the modular apparatus 100.

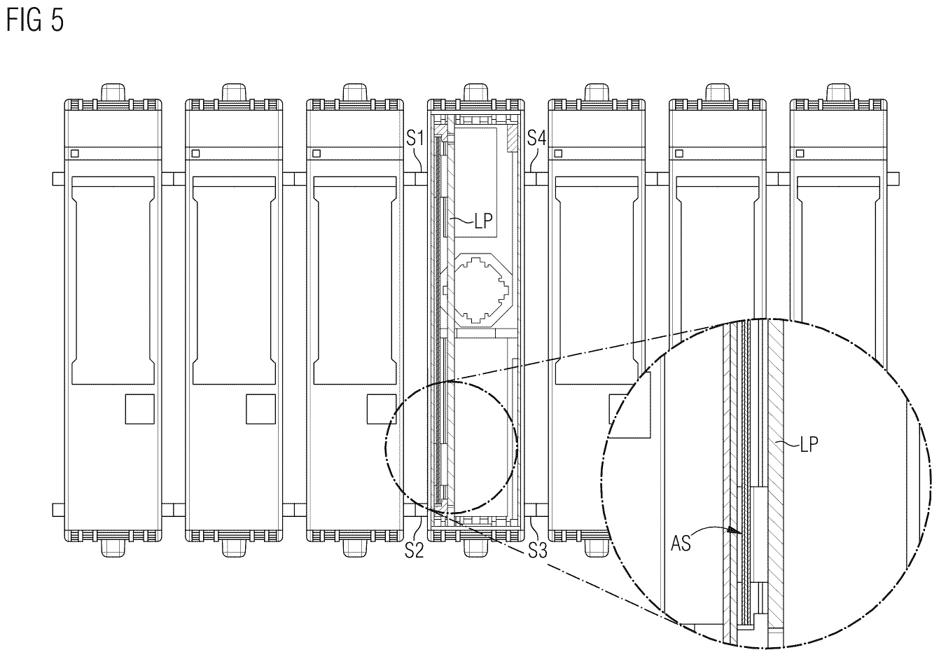

FIG. 5 once again shows the modular apparatus 100 with the automation assemblies 1 shown in FIG. 4. The automation assembly 1 arranged in the middle is now depicted in a sectional diagram. The view onto the printed-circuit board LP, upon which the heat-emitting components are arranged, becomes clear. Arranged in the housing wall is the screening layer AS.

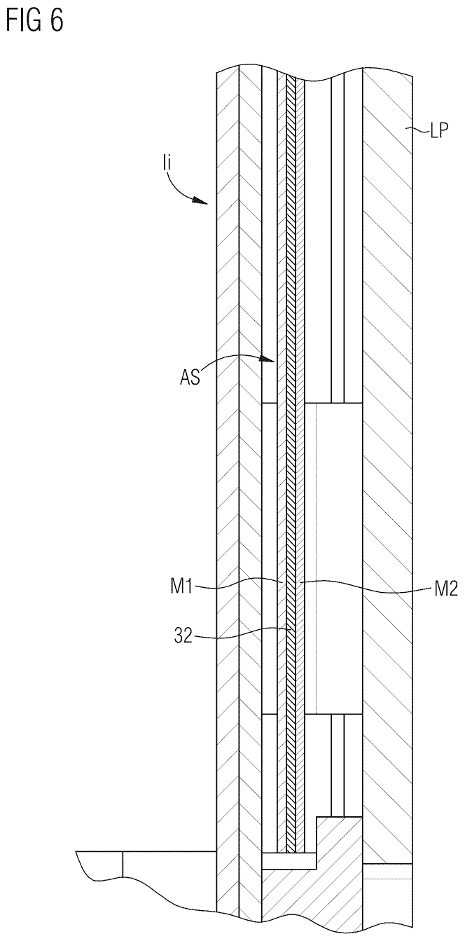

FIG. 6 shows the detailed view from FIG. 5. Arranged in the housing wall of the left side Ii is the screening layer AS with the core material 32. The screening layer AS has the first material layer M1 to its left side Ii and the second material layer M2 to its right side.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements which perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. An automation assembly comprising:
a housing having a rear side, a front side, a lower side, an upper side, a left side and a right side;
a printed-circuit board arranged in the housing and parallel between the left side and the right side of the housing, the lower side and the upper side being formed at least in part as a ventilation grille to provide convection cooling inside the housing;
wherein a housing wall of the left side and a housing wall of the right side each include a screening layer;
wherein the screening layer includes a first material layer and a second material layer, the first material layer being formed as a barrier layer, which reflects radiated heat, the second material layer being formed as a pass-through or permeable layer, which absorbs radiated heat and only partly reflects said radiated heat;
wherein the screening layer is arranged in the housing walls such that the barrier layer is arranged in a direction of an outer side of the housing and a permeable layer in a direction of the inner side of the housing.

2. The automation assembly as claimed in claim 1, wherein the screening layer is formed as a layered film, which has a core material which is coated on both sides, one side having a reflective metal layer vapor-deposited thereon, another side being provided with a lacquer, which has a heat-absorbing effect.

3. The automation assembly as claimed in claim 1, wherein the automation assembly is configured for a modular structure consisting of a plurality of automation assemblies, which are arranged next to one another and which have a backplane bus for communication with one another; wherein the rear side is configured for detachable mounting on an assembly carrier; and wherein the housing wall of the left side and the housing wall of the right side each have a spacer directed outwards.

4. The automation assembly as claimed in claim 2, wherein the automation assembly is configured for a modular structure consisting of a plurality of automation assemblies, which are arranged next to one another and which have a backplane bus for communication with one another; wherein the rear side is configured for detachable mounting on an assembly carrier; and wherein the housing wall of the left side and the housing wall of the right side each have a spacer directed outwards.

5. The automation assembly as claimed in claim 3, wherein the spacer is formed as a bar.

6. A modular apparatus comprising at least one first, one second and one third automation assembly, as claimed in one of claim 1.
